(19) United States
(12) Patent Application Publication
(10) Pub. No.: US 2012/0008801 A1
(43) Pub. Date: Jan. 12, 2012

(54) "POSSE" -- an acronym for "Personal OnStage Sound Enhancer"

(75) Inventors: Scott Morrison, Van Nuys, CA (US); Randy Sharp, Van Nuys, CA (US)

(73) Assignee: POSSE AUDIO LLC, Brea, CA (US)

(21) Appl. No.: 12/982,614

(22) Filed: Dec. 30, 2010

Related U.S. Application Data
(60) Provisional application No. 61/297,089, filed on Jan. 21, 2010.

(51) Int. Cl. H03G 3/00; H04B 1/00

(52) U.S. Cl. 381/107; 381/119; 381/109

(57) ABSTRACT

A stage monitoring system is described and claimed that provides musical performers the ability to carefully control the local sounds they are hearing during a performance independently of the house sound system and independently of the other musicians on stage. A complete and unique system constituting an improved method of monitoring oneself during an aural performance, by way of a discreet mixer that sums the collective audio signals coming from a vocal microphone, a mono or stereo instrument input, stereo ambient microphones and signals from two auxiliary inputs. The unit sends the audio signal from the ‘Instrument In’ and the ‘Vocal In’ to an audio recording console or live performance mixing console.

### PRIORITY CLAIM

This patent application claims priority as a non-provisional continuation to U.S. Provisional Patent Application No. 61/297,089 filed on Jan. 21, 2010 and hereby incorporates by reference the 61/297,089 application. This application hereby incorporates by reference U.S. Provisional Patent Application No. 61/148,950.

### SUMMARY OF THE INVENTION

“POSSE”—an acronym for “Personal OnStage Sound Enhancer” is an electronic earphone sound monitor system designed to improve a musical performer's ability to hear and control the audio blend of their own vocal, musical instrument, stereo ambient sounds, and a “house” or studio mix provided by a venue's or studio's existing monitor system. The POSSE is electrically inserted between the performer's vocal/instrument signals and the “house” public address system. This allows the performer to “tap” these signals without interruption as they are routed to the venue's public address system and stage monitor system, thereby allowing the performer to control their own in-ear monitor independent of the house system.

### BRIEF DESCRIPTION OF THE DRAWINGS

FIG. 1: Shown in FIG. 1 is an overview of the POSSE components:
1 Stand Box
2 3-foot microphone cable and connector
3 Acoustic instrument microphone
4 6-foot HDMI interface cable
5 Floor Box
6 Earphones
7 3-foot instrument cable
8 Belt Box
9 10-foot DIN interface cable

FIG. 2: The Stand Box (152 mm×40 mm×30 mm) is shown in FIG. 2. The clip located on the rear of the unit is provided for attachment to the performer's microphone stand.

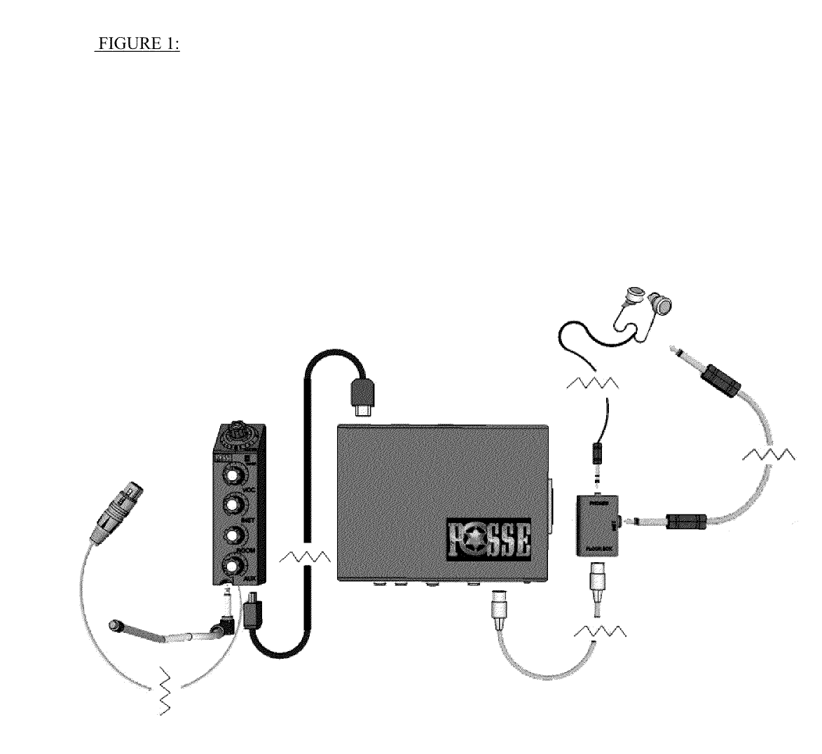

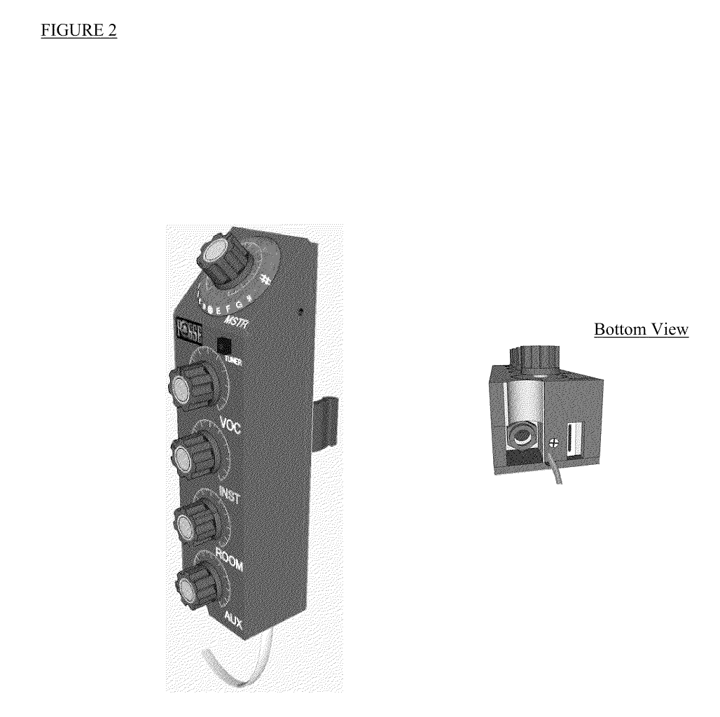

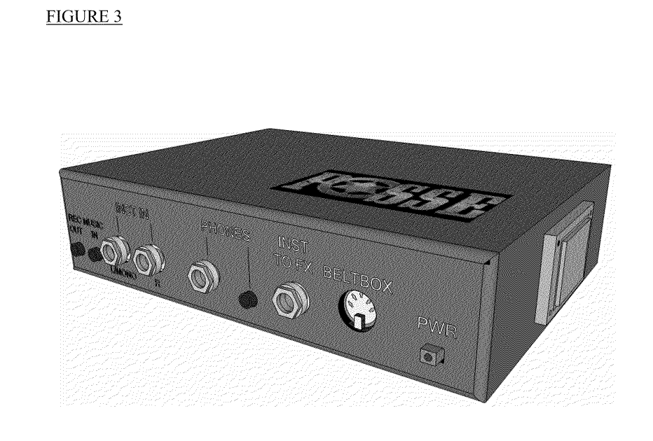

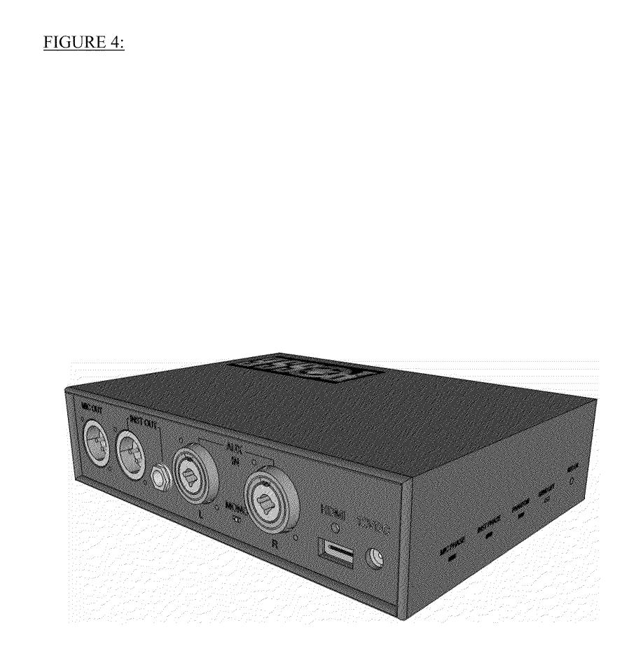

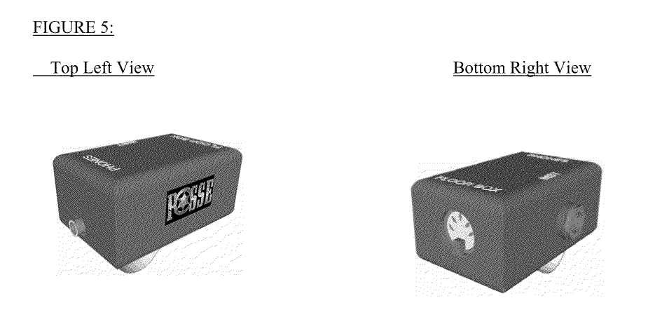

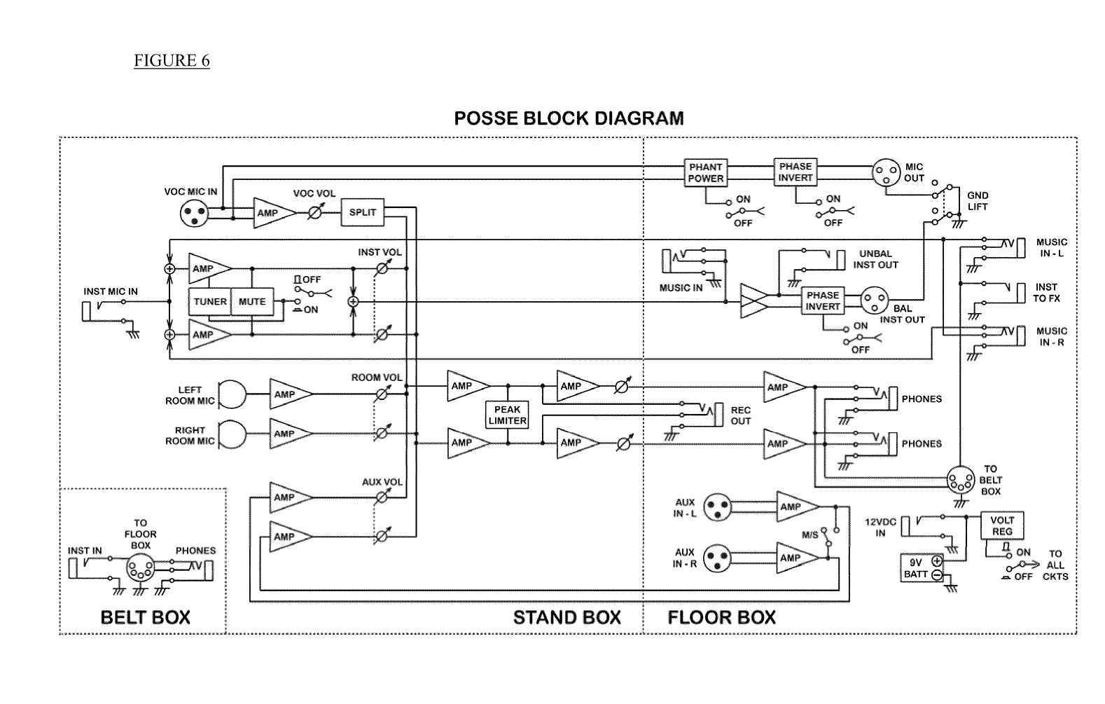

### Stand Box

10 Master volume control
11 N-Tune® instrument tuner indicator
12 Room microphone, left (not shown)
13 Room microphone, right
14 Tuner off-on/instrument mute switch
15 Microphone stand clip
16 Vocal microphone volume control
17 Instrument volume control
18 Stereo room volume control
19 Aux volume control
20 Acoustic instrument microphone input
21 HDMI Stand/Floor Box interface jack

FIG. 3: The Floor Box (195 mm×150 mm×53 mm), to be located on the floor near the performer, is shown in FIG. 3.

### Floor Box (Front)

22 ⅛″ stereo record output jack
23 ⅛″ stereo music input jack
24 ¼″ instrument input, mono/left jack
25 ¼″ instrument input, right jack
26 ¼″ stereo earphone jack
27 ⅛″ stereo earphone jack
28 ¼″ mono instrument effect send jack
29 DIN Belt/Floor Box interface jack
30 Power off/on switch
31 9-Volt battery compartment

FIG. 4: Shown in FIG. 4 is a rear view of the Floor box.

### Floor Box (Rear)

32 XLR balanced low impedance microphone output jack
33 XLR balanced low impedance instrument output jack
34 ¼″ instrument output jack
35 XLR/¼″ balanced/unbalanced high/low impedance aux input jack, left
36 Auxiliary input mono/stereo switch
37 XLR/¼″ balanced/unbalanced high/low impedance aux input jack, right
38 HDMI Floor/Stand Box interface cable jack
39 12VDC power adapter input jack
40 Vocal microphone phase switch (earphones only)
41 Instrument phase switch (earphones only)
42 Phantom power on/off and condensor microphone −3 dB pad switch
43 Ground lift switch
44 Record output level calibrate control

FIG. 5: Shown in FIG. 5 is the Belt Box (68 mm×44 mm×31 mm) which, utilizing a belt/fabric clip, provides a convenient means of locating an ⅛″ stereo earphone jack and ¼″ mono instrument jack as close to the performer as possible.

### Belt Box

45 ⅛″ stereo earphone output jack
46 ¼″ belt/fabric spring swivel clip
47 DIN Belt/Floor Box interface jack
48 ¼″ instrument input jack

FIG. 6 shows a circuit diagram for the components.

### DETAILED DESCRIPTION OF THE PREFERRED EMBODIMENTS

POSSE is comprised of several interacting components: the Stand Box, Floor Box, Belt Box and various cabling.

POSSE Design Function Overview:
Stand Box (1)—Conveniently clipped to the microphone stand within easy reach, this is what the user uses control volume and mix of the musician's vocal, instrument, the ambient sound, the house monitor, and the instrument's tuning. The Stand Box houses the stereo condenser microphones (12,13) that capture the natural ambience of the vocal, instrument, fellow performers, and the audience. An acoustic cardioid condenser instrument microphone (2) can be inserted at the base of the Stand Box to pick up audio from a non-electrified acoustic instrument. That audio information follows the same signal route as the INST IN on the floor box. The Stand Box connects to the Floor Box (5) via a 6 ft., HDMI cable (4).
Floor Box (5)—Sitting on the floor near the base of the mic stand, the Floor Box is where all signals to and from musical instruments, earphones, audio recorders, audio playback devices, the external power supply and the house PA system, are connected. The Floor Box can be controlled by the controls situated on the Stand Box.
   Belt Box (8)—Clipped to the musician's belt, instrument strap or other clothing, this unit is provided as a convenient way to eliminate the clutter of multiple instrument and headphone cables. The performer plugs their earphones (6) and their instrument cable (7) into the Belt Box. A 10 foot shielded extension cable (9), with 5-pin DIN connectors at both ends connects the Belt Box to the Floor Box. Its use is optional. If the performer prefers, the earphones, via an extension cable, and the instrument, via a regular “guitar” cord(s), can be inserted directly into the Floor Box.

How To Set Up POSSE

Set the POSSE Floor Box (5) on the floor; connect the Stand Box to the Floor Box using the 6′ HDMI cable (4); clip the Stand Box (1) to the mic stand; plug the Stand Box's hard-wired mic cable (2) into the vocal mic; plug the house mic cable into the Floor Box MIC OUT (32); plug the house instrument cable or the cable from the house “direct box” into the Floor Box INST OUT (31 or 32); Connect the 10 foot DIN cable (9) to the Belt Box (8) and the Floor Box (5) (or connect the earphones and the instrument directly to the PHONES and INST inputs on the front of the Floor Box); Attach the Belt Box to a belt (or clothing, chair, etc.), plug in the instrument; Plug in the POSSE power (or not, if using the battery), turn it on, and plug in the earphones.

If using the POSSE converter box, unplug the cable going to the stage monitor, plug it into the POSSE converter box. Plug the converter box into a POSSE AUX IN jack (35,37). (There can be a line back to the stage monitor from the converter box, if it is desired that the signal in both the POSSE and the stage monitor.) Turn on the tuner (14) for a last minute check; turn the tuner off; do a regular sound check for the mains; set your VOC, INST, ROOM, AUX, and MSTR volume levels.

For acoustic instruments, plug the Acoustic Guitar Mic (2) into the bottom of the Stand Box (1), aim the mic toward the instrument, and set it's volume with the INST volume control.

Detailed Set Up:
The musician's instrument, guitar or keyboard is plugged into the Belt Box, described above, or the INST IN jacks (24,25) on the Floor Box- one ¼″ phono plug for mono or two for stereo (in the preferred embodiment, the Belt Box is mono only but may be adapted to be stereo input). Earphones are connected to either the ⅛th″ PHONES input on the Belt Box (42) or the ⅛″ or ¼″ PHONES inputs (27,28) on the Floor Box.
   1. The included earbuds (6) or any earphones of choice (earbuds, custom-molded in-ears, regular headphones, etc.) with a ⅛″ stereo plug can be used (The Floor Box allows for a ⅛th″ or a ¼″ stereo plug). Any headphone device may be used as the musician prefers. One of the many things that the POSSE can do is add stereo room ambience to the earphone mix. The user can use either a closed-ear system to rely completely on the stereo room mics for room ambience or with an open-ear system, the stereo room mics will supplement what is being heard already hearing through your open-ear system.
   2. Connected to the Stand Box is a short microphone cable (2), which connects to the vocal microphone. The Stand Box (1) plugs into the Floor Box (5) via the provided 6 ft., HDMI interconnect cable (4).
      Signals from the vocal mic, the instrument input (24,25) and/or the instrument mic (3), are sent from the Floor Box to the house's mixing console, in the manner of a pass through signal path. That way, the signal is split to be used locally by POSSE for the local monitoring function while at the same time being sent to the house sound system.
Inserting the POSSE between the Mic/Instrument signals and the mixing console is transparent. In other words, to the house mixer, it's as if the POSSE wasn't there at all. Adjusting the levels on the POSSE will have no effect on the house mix. It will only change what you hear in your earphones.

The Stand Box Controls

Master Volume (10)

Located on the slanted upper portion of the Stand Box (1), the Master Volume controls the overall sound level in the earphones. A built-in peak limiter circuit protects the musician's hearing, protects the earphones, and provides a more consistent volume. A peak limiter circuit operates by detecting the overall signal level and lowering the gain of the circuit when the signal level reaches a predetermined threshold. This can be accomplished by a voltage controlled amplifier driven by an signal amplitude detector where an inverse proportionality of gain to signal level is set.

Tuner (11)

The TUNER button (14) turns on and off the built-in “N-Tune” chromatic tuner (11) while muting the instrument's signal going to the house mixer and the earphones. An acoustic instrument may also be tuned using the optional Acoustic Instrument Mic (3). When the built-in tuner is engaged with the switch, the POSSE automatically mutes the instrument signal.

Vocal Volume (16)

On the front face of the Stand Box just below the MSTR volume control is the VOC volume control (16) which allows the user to control the volume of the direct vocal mic signal in the earphones. This control does not affect the signal to the house PA system.

Instrument Volume (17)

Next is the INST Volume control, which allows the user to control the volume of the instrument, whether it's connected directly, or picked up by the optional Acoustic Instrument Mic (3). This control does not affect the signal to the house PA system.

Room Volume (18)

One or more condenser microphones (12,13) are located on either side of the Stand Box. A natural-sounding stereo ambience may be added to the earphone mix by use of the ROOM Volume control (18). Because these microphones are positioned just a couple of feet in front of the musician (typically on the mic stand), they not only pick up the room ambience but also provide a natural stereo image of any acoustic instrument. Adding some of the stereo ambient sound into the earphone mix makes the guitar sound fuller and more natural than otherwise possible via a direct signal.

Auxiliary Volume (19)

The Stand Box has controls that permit an AUX IN signal to be locally controlled and inserted into the earphone mix the musician is listening to. The Floor Box (5) has two AUX IN jacks (35,37) that will accept ¼″ TRS balanced or unbalanced signal jacks, or balanced XLR connectors. Either or both inputs can be switched to mono via the MONO button (36) on the Floor Box (5). The AUX Volume control (19) on the Stand Box allows the musician to control those levels in the earphone mix. The AUX inputs can be used in the following ways.

AUX IN for Live Monitoring Enhancement
A traditional stereo or mono monitor mix (as heard from stage floor monitors) can be sent from the “House” or “Stage Monitor” mixing console to the POSSE's balanced ¼″ phone or XLR AUX IN jacks (35,37). This setup would allow an artist performing with others, even a full band, to bring into their earphones, a traditional stage monitor mix. The AUX volume (19) on the Stand Box would control that level.

AUX IN for Studio Monitoring Enhancement
The POSSE can be used in the recording studio as an enhancement to the traditional headphone monitoring systems. With this system, the singer's technique to remove one earphone while singing, in order to improve the hearing of one's own pitch, is unnecessary with the addition of POSSE's ambient ROOM mic signal. Consequently, the singer will get the full energy of the direct stereo earphone mix, while still hearing themselves “in the room”.

Features:

Chromatic Tuner

A chromatic tuner is built into the POSSE system for the convenience of its use in the studio and on stage.

Adding External Effects

Signal from the REC OUT (22) on the front of the POSSE Floor Box is routed to the input of the FX processor which in most cases will require a ¼″ male phone plug. The output of the FX box typically require ¼″ male phone jacks as well. That signal can be routed into the AUX IN (35,37) jacks on the back of the POSSE Floor Box. The Effects box jacks will be either stereo or mono or a mix of both.

Routing an Instrument to an Effect

Many performers use outboard devices for their instruments, like a pre-amp or EQ. On the face of the POSSE Floor Box (5), next to the DIN connector (29) is a ¼″ phone jack called, INST TO FX (28). Using this output allows the musician to re-route the signal coming from their instrument through the DIN cable, to an external device. The output of the external device is then routed back into the Floor Box via the INST IN jack(s).

The instrument or it's preamp/processor plugs into the POSSE Floor Box INST IN input(s) (24,25) using ¼″ male phone jacks. If you plug into the L/MONO (24) input only, the signal will appear in your earphones as a mono signal. If both the L/MONO and the R inputs (25) have plugs in them, they will appear as stereo left and right signals in the earphones.
An additional effect may be achieved when the musician routes the processed signal to only the right INST IN (25) input, the original dry signal stays present on the left side.

The POSSE For Recording Your Performances

POSSE includes a REC OUT jack (22) on the POSSE Floor Box. This sends the same mix that the musician hears in the earphones. Using a stereo recorder, like the small digital voice recorders that have several hours of recording time, the musician can easily and inexpensively capture all of their performances. Located on the side of the POSSE Floor Box is a volume adjustment (44) that allows you to match the POSSE's signal to your recording device. Unlike a mix taken directly from the house mixer, this mix can include the stereo ROOM mics.

A cable with a ⅛″ stereo phone plug (“mini” plug) at both ends is typically required. The cable will run from the REC OUT jack (22) on the front of the Floor Box to the mic input (or MIC/LINE input) of the recording device. If the recorder uses a different type of connector (for example: two RCA jacks), adapters will be needed.

Controlling The Intermission Music

To control the set break music in between performances, a hand held, digital music device (iPOD, MP3 player, CD player) can be plugged directly into the MUSIC IN ⅛″ stereo jack (23), which in turn feeds the house system via the INST OUT jacks, and have the selected music playing during the breaks. The playback level is controlled by the volume controller on the Ipod, MP3, etc., being used.

POSSE Microphone Technique for Non-Electrified Acoustic Instruments

When you plug the optional “goose-neck” Acoustic Instrument Mic (3) into the Stand Box (1), the signal for the now detected guitar, fiddle, mandolin, etc., goes out the INST OUT jacks (33,34) to the house mixer; to the POSSE earphone mixer, and to the N-Tune tuner.

POSSE For Practicing

To avoid disturbing neighbors while practicing on an electric guitar or electronic keyboard, the musician can plug their instrument or it's preamp/processor into the POSSE stereo or Mono INST IN input(s) and listen through the earphones. The musician can also add a music source (MP3 player, CD player, minidisk, etc.) Into the AUX IN inputs, set the relative levels, and play along.

Studio Headphone Enhancement

There is more than one way to incorporate the POSSE into a typical studio earphone monitoring system: If the studio is set up to send the individual left and right earphone signal to the POSSE via XLR or ¼″ TRS lines, the POSSE's AUX IN inputs (35,37) can handle those signal sources. The musician would then use the AUX volume control (19) as an earphone or ‘Cue’ mix master. If the only option in the studio is a typical ¼″ stereo or ⅛″ stereo earphone jack, then a converter cable going from the ¼″ stereo or ⅛″ stereo jack from the studio cue mix output to the POSSE's two ¼″ mono or XLR AUX IN inputs (35,37), would have to be used.

Once installed, the POSSE allows the musician to mix in some ambient sound from the ROOM mics. (18) Many singers find that they sing better and don't have to remove one earphone to keep in tune. Consequently, they get to perform to the full impact of the stereo “Cue” mix.

Traditional Stage Monitoring

Even though the POSSE was originally conceived of as a tool for an artist performing alone or in an intimate “Writer's in the Round” environment, it works just as well with a full band. One or two audio lines can be run from the Main mixing board or the stage monitor mixing board to the POSSE Floor Box AUX IN (35,37). Typically, that signal will come from a ‘Cue’, or ‘Aux’ send on the house mixing board. Most multiple conductor audio signal snakes allow for return lines to the stage in the form of balanced XLR or balanced ¼″ phone jacks. The POSSE AUX IN, can handle either. If the musician is in a smaller venue where the board is just off-stage and there is no snake (multi line, audio cable) to deal with, regular ¼″ mono audio cables can be used.

Alternatively, if the house system can't run lines back to the POSSE AUX inputs, the musician can use a POSSE converter box to convert the powered signal going to the stage floor monitors into a line level signal that can then plug into a POSSE AUX IN jack (35,37). The converter box has an assortment of connector types allowing you to either replace the stage monitor with the POSSE or insert the POSSE into a series of monitors. The last arrangement allows you to have both the stage monitors and the POSSE active at the same time. One strong advantage to using the converter box is the ability to do a full setup without having to rely on the house sound person for any assistance. The converter box contains an ohmic circuit that reduces the signal power that arrives from the stage monitor amplifiers down to an appropriate line level signal. In one embodiment, the POSSE is protected by having the AUX IN jack contain a fuse, circuit breaker or other overload protection device in case the level entering the AUX IN from the powered stage monitor lines is too high.

The AUX volume (19) on the Stand Box becomes the master volume control for the monitor signal coming from the House mixing board. The sounds being produced by the musician's stage mates that cannot be picked up through the POSSE's ROOM mics (12,13) can be brought up by the house sound mixer via this connection. The musician will still have the ability to bring the overall monitor mix from the House mixing board up or down and the personal vocal, instrument and ambient ROOM mic levels up or down. Those options give the musician a much better chance of getting the mix that you want to hear.

Self Monitoring for Orchestra and Big Band Musicians
1. A member of a large musical group, like an orchestra or a big band, can carry a small mic stand and mic that can be set up directly in front of them. The signal would not necessarily route to the house PA system but would be used by the musician to hear him or herself over the collective volume level of the group. The player could adjust the ratio of themselves to the group via the VOC (16) and ROOM (18) volume controls. The musician can alternatively, plug the Acoustic Instrument microphone (3) into the Acoustic Microphone input (20) on the Stand Box (1), allowing him or her to use the N-Tune tuner (11). This action moves the control of the instrument's volume to the INST (17) knob on the Stand Box.
2. A small condenser clip-on mic (optional) can be inserted into the Acoustic Microphone input (20) on the Stand Box (1) and then clipped to the player's instrument. In this arrangement, the instrument's sound can be adjusted via the INST control on the Stand Box. This way the musician can use the tuner to tune their instrument and they don't require a mic stand or a vocal microphone. The POSSE components can then be tucked away more discreetly.

Using Wireless Systems With POSSE
Wireless transmitters will connect and work well with POSSE. The dimensions of the Floor Box (5) allow a transmitter(s) to rest squarely on top. The primary advantage of installing a wireless system using the POSSE (as opposed to installing it at the House PA mixing board) is that the musician can install and operate it themselves. Not being reliant on the house sound person can be a great advantage.

Wireless Earphones—
The wireless system transmitter get's it's signal directly from the POSSE PHONES (26 or 27) output, eliminating the need to use a wired connections to your earphones. A typical wireless configuration transmits a “monitor” mix from the House system. In this application, the wireless earphones will instead receive a mix from the POSSE.

Wireless Instrument—
The wireless receiver sends it's signal to the INST IN (24,25) in the same manner as a wired instrument would.

Wireless Mic—
The wireless transmitter sends it's signal out the ‘Microphone Cable and Connector’ (2) attached to the Stand Box (1). (an additional standard microphone cable may be required) From there the signal routes, just as the wired version does.

Other Details

Instrument Stereo Inputs

A stereo option on the POSSE Floor Box INST IN (22,23), was to allow for more elaborate guitar rigs and stereo keyboards. Some performers run their guitars through processors that provide stereo outs. Most venues cannot route a stereo signal or they discourage a performer from running a stereo signal to the main speakers because the typical distance between the cabinets provide the optimum stereo effect to only a few listeners in the middle of the room. Back to the idea that when a performer sounds great in his or her own monitor system they will give a better performance . . . the POSSE can provide the performer with the full effect of their instrument's stereo sound while sending a combined left/right mono version to the house speakers.

Phantom Power

Phantom power is built into the POSSE. Performing artists that are carrying high-quality condenser mics will require phantom power. Inevitably, those performers will find themselves in a situation where the house system's phantom power is not working or unreliable. By turning on a switch in the POSSE Floor Box (42), the performer can use their favorite condenser mic, knowing that the phantom power source is strong and dependable. Because some mics out there don't like to see phantom power, we have made it a little harder to turn the phantom power on (not that much). The POSSE ships with the phantom power switch in ‘off’ position. When the Phantom power switch is engaged, the vocal mic signal will have a 3 db attenuation to compensate for the higher gain of the vocal condenser mic. If the phantom power supplied by a house system works with your mic, you may want to turn the POSSE's phantom power off to save battery life.

Battery Power Option

The POSSE comes with an external 12-Volt DC power supply as the power source. In addition, a 9-Volt battery option is provided. When the POSSE “sees” the 12-Volt power supply (39), it ignores the battery. When the 12-Volt power supply is not present, POSSE switches to the battery for power. The power switch on the front of the Floor Box must be on for either power source to work.

The Chromatic Tuner

By mounting the ‘N-Tune’ chromatic tuner (11) in the POSSE Stand Box, it is placed it right in front of the musician and out of the audience's sight. When the musician pushes the TUNER button (14), the chromatic tuner lights up, telling the musician that it's on, mutes the guitar (or other instrument) to the main speakers and the earphones, and allows the musician to continue to make eye contact with your audience while the musician tunes the instrument.

Phase Switches

Because the POSSE headphone mix might have some of the vocal and your instrument coming from both the “AUX” mix and the VOC and INST signal paths, it's possible that the vocal and/or instrument may sound out of phase in your earphones. To allow for that possibility, there are phase switches for your vocal (40) and for your instrument (41) on the side of the POSSE Floor Box. The Phase switches only effect the sound of the voice and/or instrument in the earphones.

What is claimed:

1. A sound monitoring system comprised of:
A local mixing circuit that receives a plurality of signals transmitted over a corresponding plurality of wires;
Said local mixing circuit further comprising at least one external microphone input to receive a local ambient sound.

2. The system of claim 1 further comprising: a vocal microphone, a mono or stereo instrument input and signals from two auxiliary inputs.

3. The system of claim 1 further comprising a signal routing and amplification component where the output of the amplification component contains a mix of a signal received from the ambient microphones.

4. The system of claim 2 further comprising a chromatic tuner and a switch, such that when the switch is engaged, the chromatic tuner signal is routed to the amplifier output and the an instrument output signal from the signal router is muted.

5. The system of claim 1 further comprising a module mountable on a microphone stand comprised of a microphone input jack integral to the housing of the mounted module, said input jack operatively connected through a microphone preamp to the mixing console.

6. The system of claim 1 where the microphone inputs are equipped with a phantom power and an engagement switch, whereby engagement of the phantom power onto the microphone signal wires also engages a gain reduction circuit to be applied to the gain of the microphone input to the mixing console.

7. The system of claim 1 where at least one of the plurality of signal inputs has a input phase switch that when engaged, switches the phase of the signal relative to its phase prior to engagement.

8. The system of claim 3 further comprised of a junction box, said junction box comprised of an attachment device to attach said junction box to the performer's belt or clothing, said junction box providing as output earphone jacks, an instrument cable and a control cable that connects to a Floor Box.

9. The system of claim 1 further comprising a wireless headphone transmission and instrument transmission system to replace any wires between earphones and the console or between an instrument and the console.

10. A stage monitoring system comprised of a first unit containing controls for volume and mix of one or more of a musician's vocal, instrument, the ambient sound, the house monitor, and the instrument's tuning; the first unit containing further controls for volume of a plurality of other inputs; a second unit operatively connected to and controlled by the first unit that routes all of the signals controlled by the first unit.

11. The system of claim 12 further comprising a third unit adapted to be operatively attached the musician's belt, instrument or clothing that is further comprised of earphone signal output jacks and an instrument cable input jack, said third unit operatively connected to the second unit.

12. A stage monitoring system comprising a routing means that receives a plurality of signals and routes the signal between one or more outputs of the routing means and a control means comprised of control input means that controls the routing means so that at least one output of the routing means is adjusted by a corresponding control input means on the control means.

13. The system of claim 12 where the control means further comprises at least one ambient microphone input whose signal may be mixed into at least one output of the routing means.
